(19) United States
(12) Patent Application Publication
(10) Pub. No.: US 2025/0393333 A1
(43) Pub. Date: Dec. 25, 2025

(54) STRUCTURE AND MANUFACTURING METHOD FOR PHOTO COUPLER SINGLE CHIP

(71) Applicant: Taiwan-Asia Semiconductor Corporation, Hsinchu City (TW)

(72) Inventors: Kun-Li Lin, Hsinchu City (TW); Chuan-Wei Chen, Hsinchu City (TW); Jun-Ying Lin, Hsinchu City (TW)

(21) Appl. No.: 18/951,869

(22) Filed: Nov. 19, 2024

(30) Foreign Application Priority Data
Jun. 21, 2024 (TW) 113123244

(51) Int. Cl. H01L 31/153; H01L 31/18

(52) U.S. Cl. CPC H10F 55/155; H10F 71/1272

(57) ABSTRACT

A photo coupler single chip structure and a manufacturing method thereof are provided. The photo coupler single chip structure includes an epitaxial substrate, a light-emitting unit, an electrical insulation layer and a light-receiving unit. The light-emitting unit is disposed on the epitaxial substrate. The electrical insulation layer is disposed on the light-emitting unit. The light-receiving unit is disposed on the electrical insulation layer. The light-emitting unit can form an optical signal in response to an input signal. The light-receiving unit will directly absorb the optical signal through the electrical insulating layer and convert it into an output signal.

### CROSS-REFERENCES TO RELATED APPLICATIONS

This application claims the benefit of priority to Taiwanese Patent Application No. 113123244 filed on Jun. 21, 2024, which is hereby incorporated by reference in its entirety.

### BACKGROUND OF THE INVENTION

### Field of the Invention

The present invention relates to a photo coupler device and a manufacturing method thereof, in particular to a photo coupler single chip structure having both a light-emitting unit and a light-receiving unit on a single chip and a manufacturing method thereof.

### Descriptions of the Related Art

A photo coupler device is an electronic device that uses light to transmit electrical signals. Typically, it comprises two chips with different functions: a light-emitting diode (LED) and a light detection unit, such as a phototransistor or photodiode for achieving electrical insulation and signal transmission. This design ensures no direct electrical connection between the input and output circuits. Consequently, it provides high voltage insulation and noise suppression.

As shown in FIG. 1, conventional photo coupler devices can generally be classified into horizontally and vertically arranged packaging structures. In the horizontally arranged packaging structure of the photo coupler device 1, the LED 10 and the light detection unit 20 are disposed opposite each other on the left and right sides inside the photo coupler device 1. In the vertically arranged packaging structure of the photo coupler device 1, the LED 10 and the light detection unit 20 are disposed opposite each other on the top and bottom inside the photo coupler device 1. However, regardless of whether the structure is horizontally or vertically arranged in the photo coupler device 1, the LED 10 and the light detection unit 20 are separate and independent chips. On the path of optical signal transmission, the optical signal generated by the LED 10 must pass through the air or the encapsulating medium outside the LED 10 before being received by the light detection unit 20. In this way, the optical signal transmission will result in a significant loss in the external quantum efficiency of the LED.

Additionally, in view of the arrangement of physical structures, these two independent chips, the LED and the light detection unit, must be separately mounted onto the lead frame to form the final device. Therefore, conventional photo coupler device require space to arrange two independent chips and the lead frame, occupying a substantial volume once assembled. Moreover, the manufacturing process is complex and costly. These issues, such as the light signal transmission path, excessive device volume, and high manufacturing costs, need urgent improvement for the conventional photo coupler devices.

### SUMMARY OF THE INVENTION

The main objective of the present invention is to provide an innovative photo coupler single chip structure and the manufacturing method thereof. The present invention can not only increase the external quantum efficiency of the light-emitting diode, but also reduce the overall volume of the photo coupler device to achieve thinner package and reduce process time and cost.

To achieve the above objective, the present invention discloses a photo coupler single chip structure which includes an epitaxial substrate, a light-emitting unit, an electrical insulation layer and a light-receiving unit. The light-emitting unit is disposed on the epitaxial substrate. The electrical insulation layer is disposed on the light-emitting unit. The light-receiving unit is disposed on the electrical insulation layer. The light-emitting unit can form an optical signal in response to an input signal. The light-receiving unit will directly absorb the optical signal through the electrical insulating layer and convert it into an output signal.

In one embodiment of the photo coupler single chip structure of the present invention, the difference in lattice constant of the materials of the light-emitting unit, the light-receiving unit and the electrical insulation layer is not greater than 0.4 Angstroms (Å).

In one embodiment of the photo coupler single chip structure of the present invention, the energy band gap of the light-emitting unit is not less than the energy band gap of the light-receiving unit.

In one embodiment of the photo coupler single chip structure of the present invention, the energy band gap of the electrical insulation layer is at least 0.1 eV larger than the energy band gap of the light-emitting unit.

In one embodiment of the photo coupler single chip structure of the present invention, the epitaxial substrate is a gallium arsenide (GaAs) substrate.

In one embodiment of the photo coupler single chip structure of the present invention, the electrical insulation layer includes an N-type/P-type indium gallium phosphide (InGaP) reverse-biased interface layer and the doping concentration of the N-type/P-type indium gallium phosphide reverse-biased interface layer is less than 10¹⁷/cm³.

In one embodiment of the photo coupler single chip structure of the present invention, the light-emitting unit has a pair of positive and negative electrodes, disposed on the light-receiving unit and penetrating the light-receiving unit and electrically connecting to the light-emitting unit.

In addition, the present invention further disclosed a photo coupler single chip structure which comprises an epitaxial substrate a light-receiving unit, an electrical insulation layer, and a light-emitting unit. The light-receiving unit is disposed on the epitaxial substrate. The electrical insulation layer is disposed on the light-receiving unit. The light-emitting unit is disposed on the electrical insulation layer. The light-emitting unit can form an optical signal in response to an input signal, and the optical signal will be directly absorbed and converted into an output signal by the light-receiving unit through the electrical insulating layer.

In one embodiment of the photo coupler single chip structure of the present invention, the light-receiving unit has a pair of positive and negative electrodes, disposed on the light-emitting unit and penetrating the light-emitting unit and electrically connecting to the light-receiving unit.

To achieve the above objective, the present invention discloses a manufacturing method of a photo coupler single chip structure comprising the following steps. First, provide an epitaxial substrate. Next, provide a light-emitting unit, disposed on the epitaxial substrate. Then, provide an electrical insulation layer, disposed on the light-emitting unit. Finally, provide a light-receiving unit, disposed on the electrical insulation layer. The light-emitting unit can form an optical signal in response to an input signal, and the optical signal will be directly absorbed and converted into an output signal by the light-receiving unit through the electrical insulating layer.

In one embodiment of the manufacturing method of a photo coupler single chip structure of the present invention, the steps of providing a light-emitting unit, an electrical insulation layer and a light-receiving unit are made epitaxially on the epitaxial substrate by metal-organic chemical vapor deposition.

In one embodiment of the manufacturing method of a photo coupler single chip structure of the present invention, the manufacturing method further comprises a step of forming a pair of positive and negative electrodes electrically connecting to the light-emitting unit and the light-receiving unit respectively, wherein the pair of positive and negative electrodes of the light-emitting unit penetrate the light-receiving unit.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a cross-sectional schematic diagram of two conventional photo coupler devices;

FIG. 2 to FIG. 4 are cross-sectional schematic diagrams of the manufacturing process of the photo coupler single chip structure according to the present invention;

FIG. 5 is a top view schematic diagram of the electrode layout of the photo coupler single chip structure according to the present invention; and

FIG. 6 is a flowchart of the manufacturing process of the photo coupler single chip structure according to the present invention.

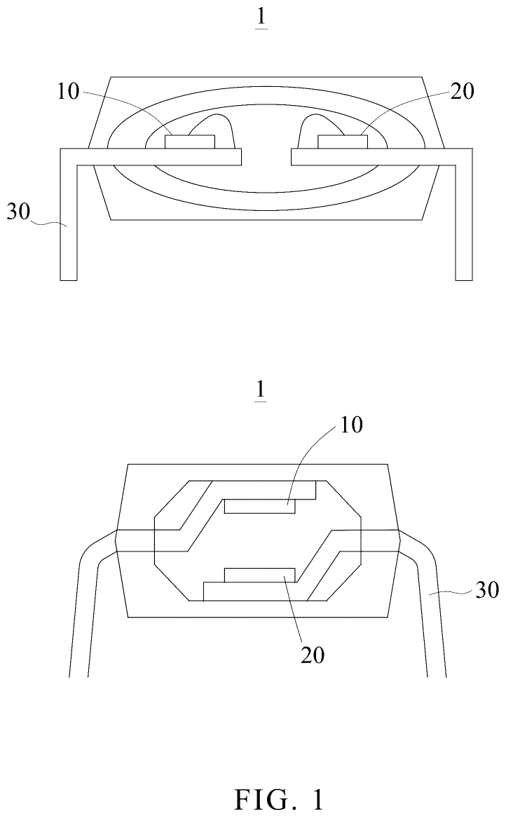

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

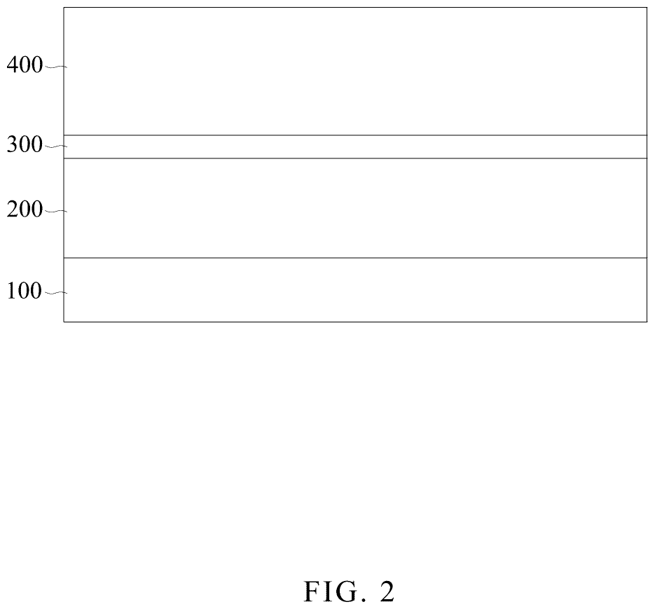

The present invention discloses a photo coupler single chip structure and a manufacturing method thereof. Referring to FIG. 2, first, an epitaxial substrate 100 is provided, which can be, but not limited to, a gallium arsenide (GaAs) wafer. Next, a light-emitting unit 200, an electrical insulation layer 300, and a light-receiving unit 400 are sequentially formed on the epitaxial substrate 100 by metal-organic chemical vapor deposition (MOCVD). It should be noted that another vertical structure of the photo coupler single chip of the present invention can also have the light-emitting unit arranged below the light-receiving unit. That is, the light-receiving unit, the electrical insulation layer, and finally the light-emitting unit are sequentially formed on the epitaxial substrate. This vertical structure is also within the claimed scope of the photo coupler single chip structure of the present invention. However, for simplicity, the structure shown in FIG. 2 will be used as an example for illustration.

It should be noted that in order to achieve the epitaxial formation of the aforementioned three functional units, comprising the light-emitting unit 200, the electrical insulation layer 300, and the light-receiving unit 400, on the same epitaxial substrate, the materials for each of these functional units must be chosen with substantially similar lattice constants. Specifically, the difference in lattice constant between the materials of each layer should not exceed 0.4 Angstroms (Å) for facilitating the smooth epitaxial growth of materials on a single wafer. Furthermore, as illustrated in FIG. 2, since the light-emitting unit 200 in this photo coupler single chip structure is in direct contact with the epitaxial substrate 100, the waste heat generated by the light-emitting unit 200 during its operation can be directly dissipated through the epitaxial substrate 100, thereby improving the performance of the device.

Furthermore, as clearly shown in FIG. 2, unlike conventional photo coupler devices, one of the technical features of the photo coupler device disclosed in the present invention is that it is a single chip structure. That is, as illustrated in FIG. 2, the light-emitting unit 200 and the light-receiving unit 400 are sequentially formed on a single wafer using epitaxial growth. Furthermore, an electrical insulation layer 300 is arranged between the light-emitting unit 200 and the light-receiving unit 400 to serve as electrical isolation. This design of a single-chip structure overcomes the issues of excessive size, high manufacturing costs, and poor external quantum efficiency associated with conventional technology.

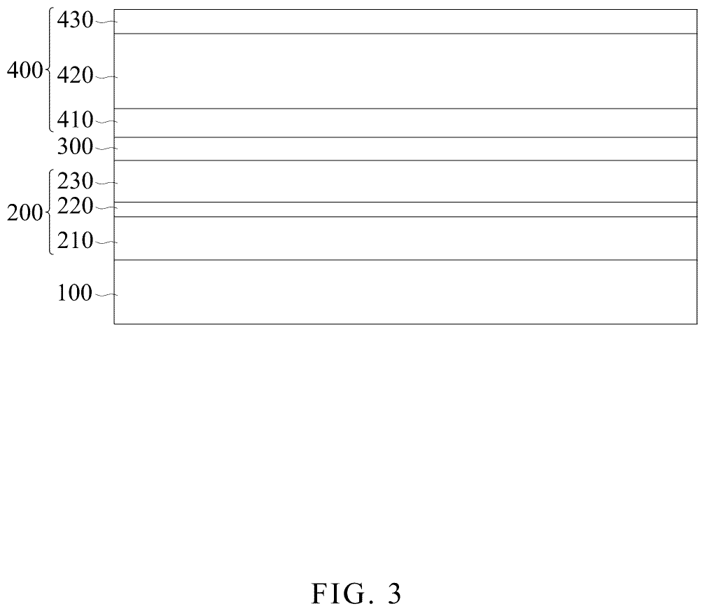

Referring to FIG. 3, it is clearly shown the structure and composition of each layer of the light-emitting unit 200, the electrical insulation layer 300, and the light-receiving unit 400 in a specific embodiment of the photo coupler single chip structure of the present invention. Specifically, a gallium arsenide (GaAs) buffer layer can be provided between the epitaxial substrate 100 and the light-emitting unit 200 for lattice adjustment required for subsequent epitaxial growth. The light-emitting unit 200 may be, but not limited to, a Group III-V epitaxial composite layer, which sequentially includes an N-doped epitaxial layer 210, a multiple quantum well (MQW) 220, and a P-doped epitaxial layer 230. In this embodiment, the N-doped epitaxial layer 210 can be a ternary compound semiconductor layer, such as an N-type indium gallium phosphide (InGaP) heavily doped epitaxial layer, serving as the N-type contact layer. Similarly, the P-doped epitaxial layer 230 can be a ternary compound semiconductor layer, such as a P-type indium gallium phosphide (InGaP) heavily doped epitaxial layer, serving as the P-type contact layer. The multiple quantum well 220 may use aluminum gallium arsenide (AlGaAs) ternary material as the barrier layer and gallium arsenide (GaAs) as the well layer. Additionally, intrinsic spacer layers, such as undoped AlGaAs, can be provided outside the barrier and well layers to prevent dopant diffusion into the quantum well structure for thereby improving the confinement efficiency of electrons and holes in the quantum well.

Additionally, it is preferable to selectively arrange a distributed Bragg reflector (DBR) layer, such as an aluminum gallium arsenide/aluminum arsenide (AlGaAs/AlAs) stack, between the N-doped epitaxial layer 210 and the multiple quantum well 220. This prevents photons from escaping towards the substrate for thereby increasing the number of photons reflected upwards and enhancing the light extraction efficiency of the LED. Furthermore, an N-doped layer, such as an N-type AlGaAs layer, can be provided between the N-doped epitaxial layer 210 and the multiple quantum well 220 to supply a high concentration of free electrons for aiding in the effective injection of electrons into the MQW structure. A P-doped layer, such as a P-type AlGaAs layer, can also be provided between the P-doped epitaxial layer 230 and the multiple quantum well 220 to supply a high concentration of free holes for aiding in hole injection into the MQW structure. This forms a barrier corresponding to the N-type AlGaAs layer for promoting effective recombination of electrons and holes.

Please continue to refer to FIG. 3, which details the structure and composition of the light receiving unit 400 in one specific embodiment of the photo coupler single chip structure of the present invention. As shown in FIG. 3, the light receiving unit 400 of the present invention is a typical photodiode structure that can convert the light signal emitted by the light-emitting unit into an electrical signal. Its structure generally includes an N-type heavily doped layer 410, an intrinsic layer 420, and a P-type heavily doped layer 430. The N-type heavily doped layer 410 can be an N-type indium gallium phosphide (InGaP) heavily doped epitaxial layer that provides a high concentration of free electrons and serves as the N-type contact layer. Similarly, the P-type heavily doped layer 430 can be a P-type indium gallium phosphide (InGaP) heavily doped epitaxial layer that provides a high concentration of free holes and aids in the injection of holes into the intrinsic layer 420. Furthermore, in this embodiment, the intrinsic layer 420 can be an undoped or lightly doped gallium arsenide (GaAs) layer that serves as the active region of the photodiode. The photons emitted by the light-emitting unit are absorbed in this region for generating electron-hole pairs. The thickness of the intrinsic layer is designed to adjust light absorption and quantum efficiency.

Additionally, in the specific embodiment, an additional spacer layer can be provided between the intrinsic layer 420 and the N-type heavily doped layer 410, as well as the P-type heavily doped layer 430. For example, an undoped aluminum gallium arsenide (AlGaAs) layer can be used as the spacer layer to prevent the diffusion of dopants from the N-type and P-type heavily doped layers into the active region. Furthermore, an N-type doped layer can be disposed between the spacer layer and the intrinsic layer 420, such as an N-type aluminum gallium arsenide (AlGaAs) layer. A P-type doped layer can also be disposed between the spacer layer and the intrinsic layer 420, such as a P-type aluminum gallium arsenide (AlGaAs) layer, to provide a high concentration of free holes.

Continuing with FIG. 3, to ensure that the two different functional units, the light-emitting unit 200 and the light-receiving unit 400, can operate without interference, an electrical insulation layer 300 must be disposed on top of the light-emitting unit 200 after its epitaxial growth on the epitaxial substrate 100. In the embodiment of the present invention, this electrical insulation layer 300 can be an N-type/P-type reverse-biased interface layer, which is achieved by using a PN diode under reverse bias to create an electrical isolation effect. Specifically, a lightly doped P-type indium gallium phosphide (InGaP) layer is first epitaxially grown on the light-emitting unit 200, followed by the deposition of an N-type lightly doped indium gallium phosphide (InGaP) layer to form an N-type/P-type indium gallium phosphide (InGaP) reverse-biased interface layer for achieving electrical isolation. In a preferred embodiment, the doping concentration of this N-type/P-type indium gallium phosphide reverse-biased interface layer is less than 10¹⁷/cm³ to increase the width of the depletion region with a lower doping concentration for thereby enhancing the electrical isolation effect. Additionally, it is preferable to further epitaxially form undoped aluminum gallium arsenide (AlGaAs) as a spacer layer between the electrical insulation layer 300 and the light-emitting unit 200 and the light-receiving unit 400.

It should be noted that the structure and composition of the light-emitting unit 200, the electrical insulation layer 300, and the light-receiving unit 400 described above are merely examples and are not intended to limit the invention. Any modifications made by those skilled in the art after understanding the above contents are within the claimed scope of the present invention. However, when selecting the materials for these units, it is important to ensure that the energy band gap (Eg) of the materials forming the layers of the light-emitting unit is not smaller than the energy band gap of the materials forming the layers of the light-receiving unit. This ensures that the wavelength of the light emitted by the light-emitting unit is shorter than the wavelength of light that can be absorbed by the light-receiving unit for allowing the light signal emitted by the light-emitting unit's can be successfully absorbed and converted into an electrical signal by the light-receiving unit. Additionally, regarding the selection of materials for the electrical insulation layer, to ensure that the electrical insulation layer does not absorb the light emitted by the light-emitting unit, that is to effectively make the electrical insulation layer “transparent” to the light-emitting unit, the energy band gap of the material of the electrical insulation layer is preferably at least 0.1 eV larger than the energy band gap of the light-emitting unit material so that most of the light emitted by the light-emitting unit can be received by the light-receiving unit.

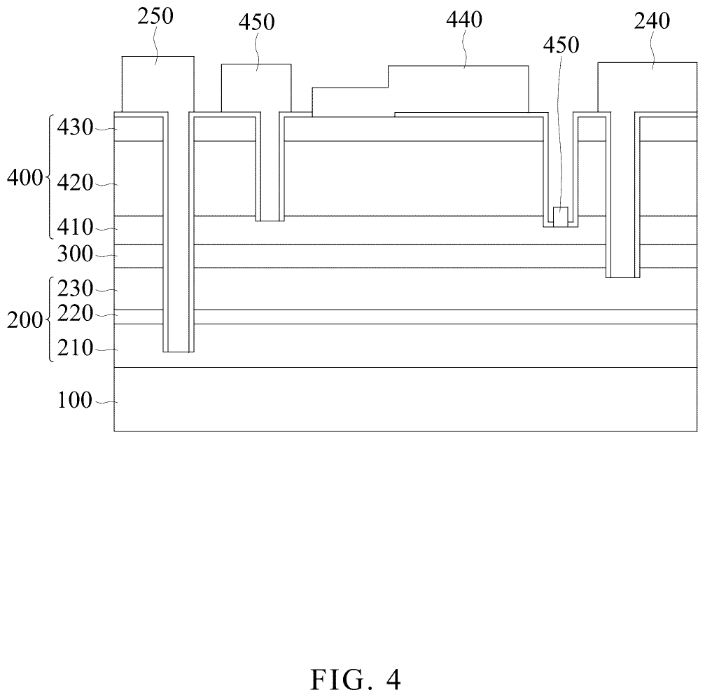

Please refer to FIG. 4, which shows a schematic diagram of the electrode design in an embodiment of the photo coupler single-chip structure of the present invention. In this design, the positive and negative electrodes of the light-emitting unit 200 (including positive electrode 240 and negative electrode 250) and the positive and negative electrodes of the light-receiving unit 400 (including positive electrode 440 and negative electrode 450) are arranged on one side of the light-receiving unit 400. The positive and negative electrodes of the light-emitting unit 200 penetrate through the light-receiving unit 400 and the electrical insulation layer 300 to electrically connect to the light-emitting unit 200. Specifically, the positive electrode 240 is electrically connected to the P-type doped epitaxial layer 230 and the negative electrode 250 is electrically connected to the N-type doped epitaxial layer 210. The positive electrode 440 of the light-receiving unit 400 is electrically connected to the P-type heavily doped layer 430, while the negative electrode 450 penetrates through the P-type heavily doped layer 430 and the intrinsic layer 420 to electrically connect to the N-type heavily doped layer 410. It should be noted that the parts of the electrodes that penetrate through the epitaxial layers must be insulated by an insulating layer to prevent short circuits. On the other hand, according to the above content, when the structure of the photo coupler single-chip is formed by epitaxially growing from the bottom up—comprising the epitaxial substrate, the light-receiving unit, the electrical insulation layer, and the light-emitting unit—the electrode design must be correspondingly adjusted. That is, the positive and negative electrodes of the light-receiving unit, disposed on the light-emitting unit, electrically connect to the light-receiving unit after penetrating through the light-emitting unit. Those skilled in the art will be able to easily extend these principles based on the above contents, so further details are omitted here.

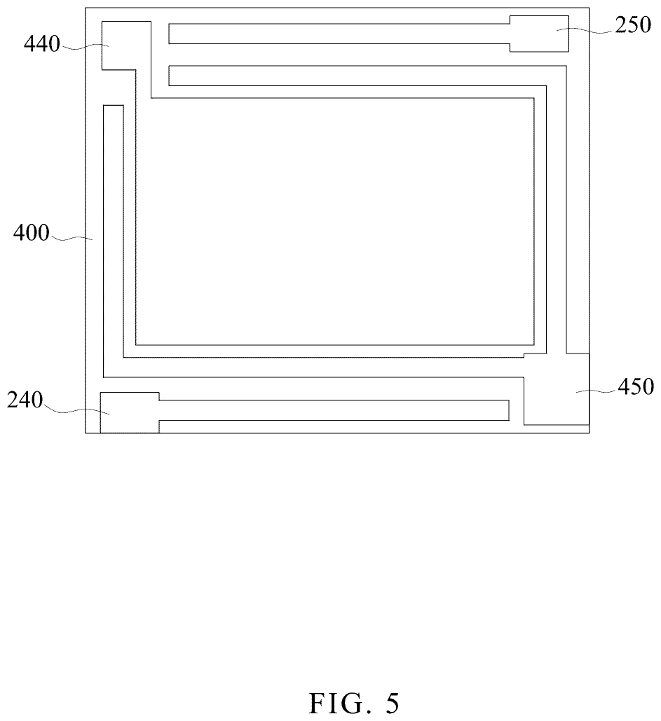

In addition, this electrode layout design can be adapted to meet the requirements of the device by configuring it as wire bonding electrodes or flip-chip electrodes to achieve further miniaturization. In a preferred embodiment, as shown in FIG. 5, the top view schematic of the electrode layout for the photo coupler single chip structure of the present invention is illustrated. FIG. 5 shows that the design increases the coverage area of the positive electrode 440 of the light-receiving unit to reflect and capture light that is emitted from the light-emitting unit but not yet absorbed by the light-receiving unit 400. This reflected light is directed back into the light-receiving unit 400 for enhancing the efficiency of the device. Additionally, in embodiments where the epitaxial substrate is an intrinsic semi-insulating substrate, if a conductive substrate is used in other embodiments, the four-electrode layout on the same side can be modified to a three-electrode layout on one side, with the fourth electrode arranged on the conductive substrate.

In summary, the photo coupler single chip structure of the present invention involves forming the light-emitting unit, electrical insulation layer, and light-receiving unit on a single wafer through epitaxial growth. Consequently, the light emitted by the LED epitaxial layer directly passes through the electrical insulation layer to be absorbed by the light-receiving unit after traversing materials with similar internal refractive indices. Accordingly, the external quantum efficiency of the LED will be significantly enhanced. In other words, the light-emitting unit in the photo coupler single chip structure of the present invention can generate an optical signal in response to an input signal, which is then directly absorbed by the light-receiving unit within the same photo coupler single-chip device through the electrical insulation layer and converted into an output signal. This overcomes the problem of light transmission paths in conventional photo coupler devices, which must pass through the exterior of the light-emitting unit before being received by the light-receiving unit, resulting in reduced optical efficiency. At the same time, the single-chip structure substantially reduces the device volume so it can meet further miniaturization requirements while also reducing processing time and manufacturing costs.

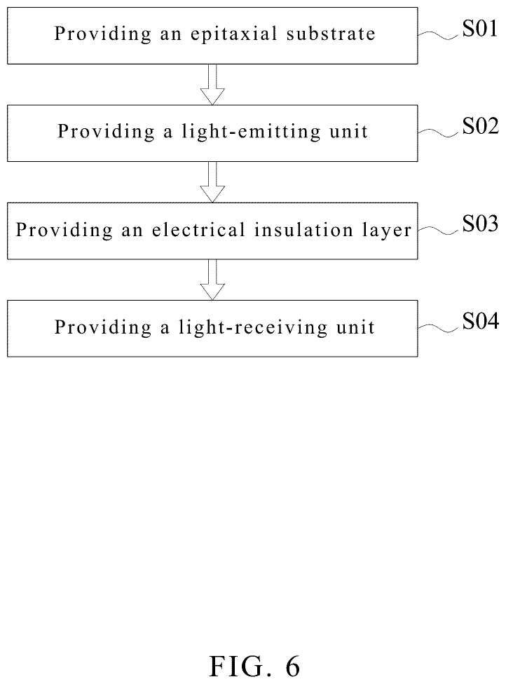

Please refer to FIG. 6, which shows a flowchart of the steps for manufacturing the photo coupler single chip structure of the present invention. First, in Step S01, a substrate is provided. Next, in Step S02, a light-emitting unit is provided, which can be a light-emitting diode (LED). Then, in Step S03, an electrical insulation layer is provided on top of the light-emitting unit. In Step S04, a light-receiving unit is provided on top of the electrical insulation layer for forming a single structure that integrates both the light-emitting unit and the light-receiving unit into a photo coupler single chip structure. Detailed descriptions of each unit can be found in the preceding sections and are not repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A photo coupler single chip structure, comprising:
an epitaxial substrate;
a light-emitting unit, disposed on the epitaxial substrate;
an electrical insulation layer, disposed on the light-emitting unit; and
a light-receiving unit, disposed on the electrical insulation layer,
wherein the light-emitting unit forms an optical signal in response to an input signal, and the optical signal is directly absorbed and converted into an output signal by the light-receiving unit through the electrical insulating layer.

2. The photo coupler single chip structure of claim 1, wherein the difference in lattice constant of the materials of the light-emitting unit, the light-receiving unit and the electrical insulation layer is not greater than 0.4 Angstroms (Å).

3. The photo coupler single chip structure of claim 1, wherein the energy band gap (Eg) of the light-emitting unit is not less than the energy band gap of the light-receiving unit.

4. The photo coupler single chip structure of claim 1, wherein the energy band gap of the electrical insulation layer is at least 0.1 eV larger than the energy band gap of the light-emitting unit.

5. The photo coupler single chip structure of claim 1, wherein the epitaxial substrate is a gallium arsenide (GaAs) substrate.

6. The photo coupler single chip structure of claim 5, wherein the electrical insulation layer includes an N-type/P-type indium gallium phosphide (InGaP) reverse-biased interface layer and the doping concentration of the N-type/P-type indium gallium phosphide reverse-biased interface layer is less than 10¹⁷/cm³.

7. The photo coupler single chip structure of claim 1, wherein the light-emitting unit has a pair of positive and negative electrodes, disposed on the light-receiving unit and penetrating the light-receiving unit and electrically connecting to the light-emitting unit.

8. A photo coupler single chip structure, comprising:
an epitaxial substrate;
a light-receiving unit, disposed on the epitaxial substrate;
an electrical insulation layer, disposed on the light-receiving unit; and
a light-emitting unit, disposed on the electrical insulation layer,
wherein the light-emitting unit forms an optical signal in response to an input signal, and the optical signal is directly absorbed and converted into an output signal by the light-receiving unit through the electrical insulating layer.

9. The photo coupler single chip structure of claim 8, wherein the difference in lattice constant of the materials of the light-emitting unit, the light-receiving unit and the electrical insulation layer is not greater than 0.4 Angstroms (Å).

10. The photo coupler single chip structure of claim 8, wherein the light-receiving unit has a pair of positive and negative electrodes, disposed on the light-emitting unit and penetrating the light-emitting unit and electrically connecting to the light-receiving unit.

11. A manufacturing method of a photo coupler single chip structure, comprising:
providing an epitaxial substrate;
providing a light-emitting unit, disposed on the epitaxial substrate;
providing an electrical insulation layer, disposed on the light-emitting unit; and
providing a light-receiving unit, disposed on the electrical insulation layer,
wherein the light-emitting unit forms an optical signal in response to an input signal, and the optical signal is directly absorbed and converted into an output signal by the light-receiving unit through the electrical insulating layer.

12. The manufacturing method of claim 11, wherein the steps of providing a light-emitting unit, an electrical insulation layer and a light-receiving unit are made epitaxially on the epitaxial substrate by metal-organic chemical vapor deposition.

13. The manufacturing method of claim 11, further comprising a step of forming a pair of positive and negative electrodes electrically connecting to the light-emitting unit and the light-receiving unit respectively, wherein the pair of positive and negative electrodes of the light-emitting unit penetrate the light-receiving unit.
